(19) United States
(12) Patent Application Publication
(10) Pub. No.: US 2011/0024913 A1
(43) Pub. Date: Feb. 3, 2011

(54) SEMICONDUCTOR DEVICE

(75) Inventor: Hiroyuki UCHIYAMA, Tokyo (JP)

Correspondence Address: YOUNG & THOMPSON, 209 Madison Street, Suite 500, Alexandria, VA, 22314, US

(73) Assignee: ELPIDA MEMORY, INC., Tokyo (JP)

(21) Appl. No.: 12/844,371

(22) Filed: Jul. 27, 2010

(30) Foreign Application Priority Data
Jul. 31, 2009 (JP) 2009-178906

(51) Int. Cl. H01L 23/52

(52) U.S. Cl. 257/773; 257/E23.141

(57) ABSTRACT

A semiconductor device includes first and second semiconductor chips. The first semiconductor chip includes a first engaging portion. The first engaging portion includes a first conductor. The second semiconductor chip includes a second engaging portion engaged with the first engaging portion. The second engaging portion includes a second conductor being electrically in contact with the first conductor.

### BACKGROUND OF THE INVENTION

1. Field of the Invention

The present invention relates to a semiconductor device.

Priority is claimed on Japanese Patent Application No. 2009-178906, filed Jul. 31, 2009, the content of which is incorporated herein by reference.

2. Description of the Related Art

Regarding a memory device, a memory embedded logic device, and the like, generally, a memory cell portion having a dedicated structure formed by a complicated process, a MOS transistor on a silicon substrate, and a logic portion including a wiring layer are formed on the same semiconductor chip.

However, when the memory cell portion and the logic portion are formed on the same semiconductor chip, the logic portion has to be subjected to a thermal treatment required for forming the memory cell portion, thereby causing degradation of device performance of the logic portion.

Additionally, when a taller capacitor, such as an STC (stacked capacitor) of a DRAM memory cell, is formed to maintain characteristics of the capacitor with miniaturization of semiconductor devices, a wiring inter-layer film of the logic portion has to be made thicker. Consequently, a through hole for connecting wirings is deep, thereby complicating the processing of wirings, increasing wiring resistance, and decreasing the reliability.

Further, regarding a transistor of the memory cell portion, a priority is given to miniaturization and a small leakage current. Regarding a transistor of the logic portion, on the other hand, a priority is given to performance. For this reason, a condition for impurity implantation differs between the memory cell portion and the logic portion, and therefore different ion implantation processes are required, thereby causing an increase in the number of processes of processing wafers and causing higher costs.

Moreover, with further miniaturization, different transistors, such as a three-dimensional transistor for a memory cell and a strained transistor for a peripheral circuit, are required for the memory cell portion and the logic portion, thereby causing an increase in the number of processes and in higher costs.

To solve the above problems, for example, when a DRAM chip 100 includes a memory cell array 101, and a low control circuit 102 and a column control circuit 103 which control the memory cell array 101, as shown in FIG. 8A, the memory cell array 101 and the low and column control circuits 102 and 103 are separately formed as different semiconductor chips 111, 112, 113 by different manufacturing processes, as shown in FIG. 8B.

Japanese Patent Laid-Open Publication No. H08-008392 discloses a method of connecting multiple semiconductor chips. Specifically, terminals 122 are formed on a side surface of a semiconductor chip 121. Receiving portions 123 are formed on a side surface of another semiconductor chip. Then, the terminals 122 are engaged with the respective receiving portions 123. Japanese Patent Laid-Open Publication No. 2005-79387 discloses a method of connecting multiple semiconductor devices.

As a method of connecting multiple semiconductor chips, for example, bonding pads 133 and 134 on semiconductor chips 131 and 132, respectively, are connected by wires 135. However, for example, more than 1000 wires are required for connecting a memory array control portion and a peripheral circuit, thereby causing difficulties.

Further, regarding the method disclosed in Japanese Patent Laid-Open Publication No. H08-008392, the terminals 122 and the receiving portions 123 have to be formed on the side surface of the semiconductor chip 121, thereby making it difficult to provide a sufficient number of wires for connecting the chips.

### SUMMARY

In one embodiment, a semiconductor device may include, but is not limited to, first and second semiconductor chips. The first semiconductor chip includes a first engaging portion. The first engaging portion includes a first conductor. The second semiconductor chip includes a second engaging portion engaged with the first engaging portion. The second engaging portion includes a second conductor being electrically in contact with the first conductor.

In another embodiment, a semiconductor device may include, but is not limited to a wiring layer and an insulating layer over the wiring layer. The insulating layer includes a receiving portion adjacent to a first side surface of the insulating layer. The receiving portion has a second side surface and a first bottom surface. The second side surface vertically extends from the wiring layer. The second side surface connects to the first side surface. The first bottom surface is a first upper surface of a first portion of the wiring layer.

In still another embodiment, a semiconductor device may include, but is not limited to a substrate and a wiring layer over the substrate. A stack of the substrate and the wiring layer includes first and second receiving portions that are adjacent to a first side surface of the stack. First and second bottom surfaces of the first and second receiving portions are included in the substrate, respectively. Second and third side surfaces of the first and second receiving portions vertically extend from the first and second bottom surfaces, respectively.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a cross-sectional view illustrating a semiconductor device according to a first embodiment of the present invention;

FIG. 2A is a perspective view illustrating a semiconductor chip according to the first embodiment;

FIG. 2B is an enlarged perspective view illustrating a part of the semiconductor chip of the first embodiment;

FIG. 3A is a perspective view illustrating a first semiconductor chip according to the first embodiment;

FIG. 3B is an enlarged perspective view illustrating a side surface of the first semiconductor chip;

FIG. 4A is a perspective view illustrating a second semiconductor chip according to the first embodiment;

FIG. 4B is an enlarged perspective view illustrating a side surface of the second semiconductor chip;

FIG. 5 is a perspective view illustrating a process of a method of forming the first and second semiconductor chips;

FIG. 6A is a plan view illustrating a process of the method of forming the first semiconductor chip;

FIG. 6B is a plan view illustrating a process of the method of forming the second semiconductor chip;

FIG. 7 is a perspective view illustrating an example of the semiconductor chip of the first embodiment;

FIG. 8A is a plan view illustrating a semiconductor chip of a related art;

FIG. 8B is a plan view illustrating a semiconductor chip of a related art including multiple separated elements that are separately formed;

FIG. 9 is a perspective view illustrating a connection of multiple semiconductor chips of a related art; and

FIG. 10 is a cross-sectional view illustrating a method of connecting multiple semiconductor chips according to a related art.

### DETAILED DESCRIPTION OF THE PREFERRED EMBODIMENTS

The present invention will now be described herein with reference to illustrative embodiments. The accompanying drawings explain a semiconductor device and a method of manufacturing the semiconductor device in the embodiments. The size, the thickness, and the like of each illustrated portion might be different from those of each portion of an actual semiconductor device.

Those skilled in the art will recognize that many alternative embodiments can be accomplished using the teachings of the present invention and that the present invention is not limited to the embodiments illustrated herein for explanatory purposes.

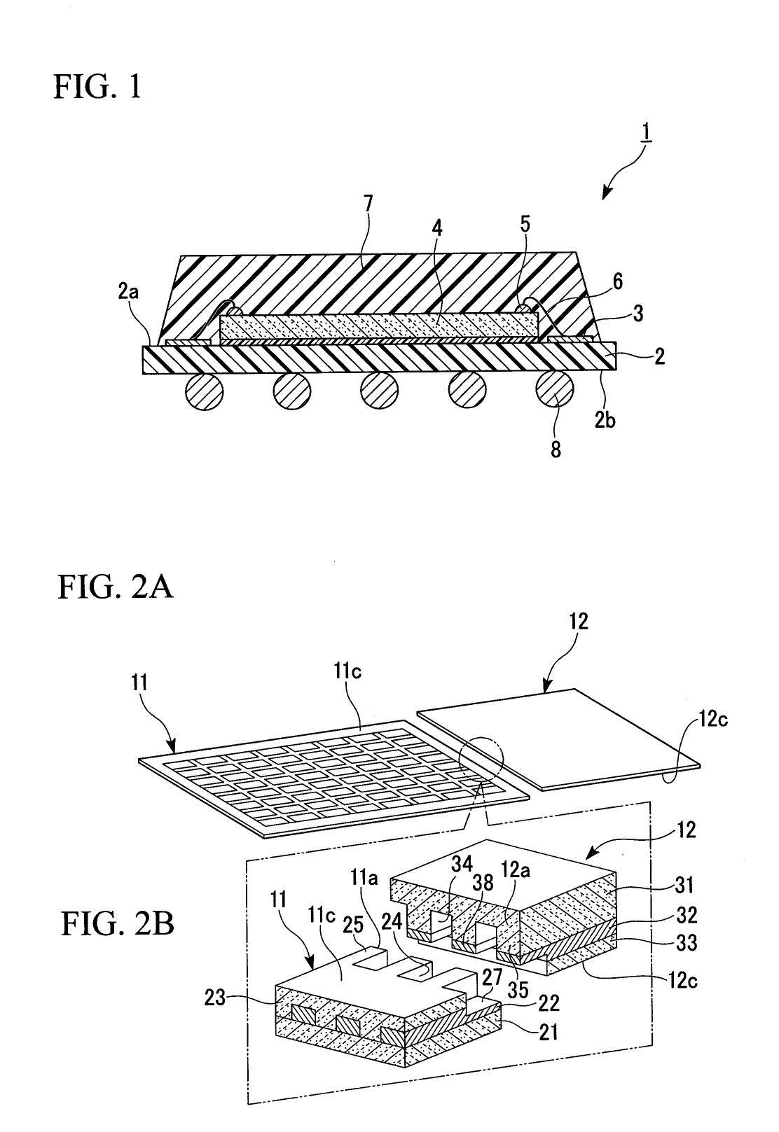

Hereinafter, a semiconductor device according to a first embodiment of the present invention is explained. Various semiconductor devices may be used in the first embodiment as long as a semiconductor chip is included therein. For example, a BGA (Ball Grid Array) semiconductor device 1 as shown in FIG. 1 may be used.

The BGA semiconductor device 1 schematically includes: a wiring board 2 having top and bottom surfaces 2a and 2b, multiple connection pads 3 being disposed on the top surface 2a, and multiple lands (not shown) being disposed on the bottom surface 2b so as to be electrically connected to the connection pads 3; a semiconductor chip 4 on the top surface 2a of the wiring board 2; wires 6 electrically connecting the electrode pads 5 on the semiconductor chip 4 to the connection pads 3 on the wiring board 2; a seal 7 made of an insulating resin, the seal 7 covering the semiconductor chip 4 and the wires 6; and external terminals (solder balls) 8 on the respective lands.

The semiconductor chip 4 includes a first semiconductor chip 11 and a second semiconductor chip 12 electrically connected to the first semiconductor chip 11, as shown in FIGS. 2A and 2B. The first semiconductor chip 11 of the first embodiment may include, but is not limited to, a circuit that directly controls a DRAM memory cell and a memory cell array. For example, the first semiconductor chip 11 may include, in addition to the memory cell array, a sense amp, a word-line driver, a data bus buffer, a switching circuit, and the like.

The second semiconductor chip 12 of the first embodiment may include, but is not limited to, a chip that is connected to a memory-cell-array control circuit that outputs/receives data and a control signal to/from an external device. For example, the semiconductor chip 12 may include, for example, a word-line switching circuit, a sense-amp selecting circuit, a main amp, an input-output circuit, and the like.

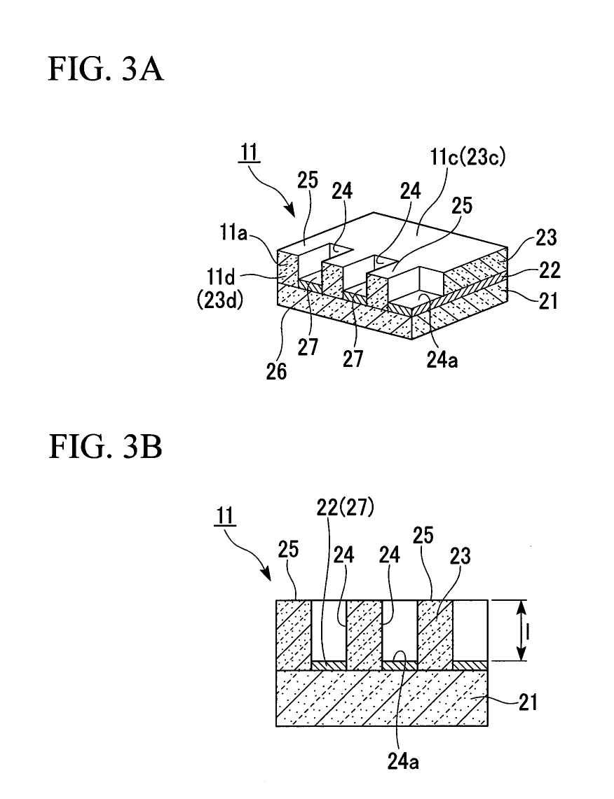

As shown in FIGS. 3A and 3B, the first semiconductor chip 11 includes a first semiconductor substrate 21, a first wiring layer 22 on the first semiconductor substrate 21, and a first insulating film 23 covering the first semiconductor substrate 21 and the first wiring layer 22.

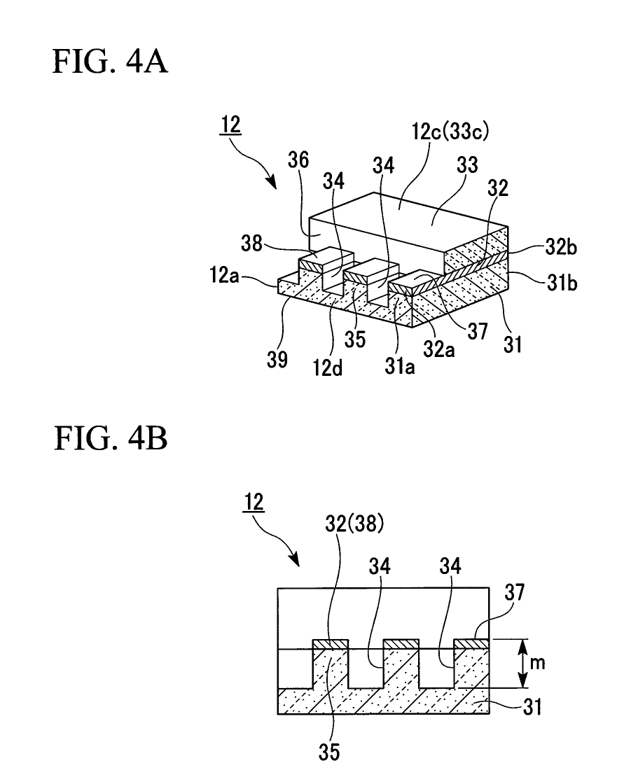

As shown in FIGS. 4A and 4B, the second semiconductor chip 12 includes a second semiconductor substrate 31, a second wiring layer 32 on the second semiconductor substrate 31, and a second insulating film 33 covering the second semiconductor substrate 31 and the second wiring layer 32.

FIGS. 3 and 4 schematically illustrate the semiconductor chips 11 and 12, respectively. Actually, the semiconductor chip 11 includes more than 1000 pieces of the first wiring layers 22 arranged at substantially the same pitch as circuit connection portions included in the semiconductor chip 11. Similarly, the semiconductor chip 12 includes more than 1000 pieces of the second wiring layers 32 arranged at substantially the same pitch as circuit connection portions included in the semiconductor chip 12.

The first semiconductor chip 11 includes multiple first receiving portions 24 adjacent to a side surface 11d of the first insulating film 23. A first extending portion 25 is defined by the two first receiving portions 24.

Specifically, multiple first receiving portions 24 are formed at a predetermined pitch adjacent to a side surface 11a of the first semiconductor chip 11. The first receiving portion 24 is in substantially rectangular in plan view. In other words, the first receiving portion 24 defines a trench groove that is semiopen. The first receiving portion 24 has a bottom surface and side surfaces vertically extending from the bottom surface. A depth of the first receiving portion 24 (i.e., a depth of the side surfaces of the first receiving portion 24) is a predetermined value 1.

The first extending portion 25 outwardly extends toward the side surface 11a of the first semiconductor chip 11. The first receiving portion 24 and the first extending portion 25 are alternately arranged along a side 26 of the first semiconductor chip 11. FIG. 3B illustrates the first receiving portion 24 and the first extending portion 25 that are horizontally viewed from the side surface 11a.

A terminal portion 27 of the first wiring layer 22 is the bottom surface 24a of the first receiving portion 24. In other words, most parts of the first wiring layer 22 are covered by the first insulating film 23. However, the first receiving portion 24 is not covered by the first insulating film 23. Therefore, the terminal portion 27 of the first wiring layer 22 is exposed.

The size of the first receiving portion 24 is determined such that one exposed terminal portion 27 corresponds to one first receiving portion 24. The first receiving portions 24 are formed so that all the terminal portions 27 to be electrically connected to the second semiconductor chip 12 are exposed. In other words, the number of the first receiving portions 24 is the same as that of the terminal portions 27 to be electrically connected to the second semiconductor chip 12, which is for example, more than 1000.

The terminal portions 27 of the first wiring layer 22 are arranged along the side 26 of the first semiconductor chip 11. Although the side surface of the terminal 27 is adjacent to the side surface 11d of the semiconductor chip 11 as shown in FIG. 3A, the side surface of the terminal 27 does not have to be adjacent to the side surface 11d as long as the upper surface of the terminal portion 27 is exposed.

The second insulating film 33 includes a cutout portion 36 on the side of the side surface 12a of the second semiconductor chip 12. Specifically, the cutout portion 36 has a side surface vertically extending from the second wiring layer 32. Second extending portions 35, which will be explained later, extend from the side surface of the cutout portion 36 to the side surface 12a of the second semiconductor chip 12. The second extending portion 35 includes a terminal portion 38, which is an exposed portion 37 of the second wiring layer 32.

Multiple second receiving portions 34 are formed in a stack of the second semiconductor substrate 31 and the second wiring layer 32. The second receiving portions 34 are adjacent to the side surface 12a of the second semiconductor chip 12. Specifically, the second receiving portion 34 has a bottom surface included in the second semiconductor substrate 31, and side surfaces vertically extending from the bottom surface. The bottom and side surfaces of the second receiving portion 34 form a semiopen trench groove, as shown in FIG. 4A. The second receiving portion 34 and the second extending portion 35 are alternately arranged along a side 39 of the second semiconductor chip 12, as shown in FIG. 4B.

The first extending portions 25 of the first semiconductor chip 11 are engaged with the respective second receiving portions 34 of the second semiconductor chip 12, and thereby the side surface 11a of the first semiconductor chip 11 is connected to the side surface 12a of the second semiconductor chip 12. Accordingly, the second receiving portion 34 is substantially the same size as the first extending portion 25. The shape of the second receiving portion 34 is substantially the same as that of the first extending portion 25 in plane view. The height 1 of the first extending portion 25 is substantially the same as the depth m of the first receiving portion 24.

The second extending portion 35 is defined by the two receiving portions 34. Thus, the second receiving portion 34 and the second extending portion 35 are alternately arranged along the side 39 of the second semiconductor chip 12, as shown in FIG. 4B. The second extending portion 35 includes the terminal portion 38, which is the exposed portion 37 of the second wiring layer 32. The second extending portion extends from the side surface of the cutout portion 36 to the side surface 12a of the second semiconductor chip 12.

Although it has been explained above that the second extending portions 35 are adjacent to the side surface 12a of the second semiconductor chip 12 as shown in FIG. 4A, the second extending portions 35 do not have to be adjacent to the side surface 12a as long as the upper surface of the terminal portion 38 is exposed.

As shown in FIGS. 2A and 2B, the side surface 11a of the first semiconductor chip 11 is electrically connected to the side surface 12a of the second semiconductor chip 12 so that the surface 11c of the first semiconductor chip 11 faces the surface 12c of the second semiconductor chip 12, thus forming the semiconductor chip 4 of the first embodiment.

Specifically, the first extending portions 25 of the first semiconductor chip 11 are engaged with the respective second receiving portions 34 of the second semiconductor chip 12. At the same time, the second extending portions 35 of the second semiconductor chip 12 are engaged with the first receiving portions 24 of the first semiconductor chip 11. Accordingly, the terminal portions 27 of the first wiring layer 22 are in contact with the respective terminal portions 38 of the second wiring layer 32, and thereby the first semiconductor chip 11 is electrically connected to the second semiconductor chip 12.

The first and second wirings 22 and 32 are arranged at the same pitch as circuit portions in the semiconductor chip. Wirings for transmitting and receiving a low-and-column switching signal, local input-and-output lines, and the like are connected to the first and second wirings 22 and 32, which is impossible in the related art.

Preferably, a bottom surface of the first receiving portion 24 is covered by a flexible metal film so that stress applied to the receiving portions 24 and 34 of the semiconductor chips 11 and 12 is reduced when the first semiconductor chip 11 is engaged with the second semiconductor chip 12.

Additionally, when the first extending portions 25 are engaged with the respective receiving portions 34, side surfaces 11d of the first extending portions 25 are preferably fixed to the side surface of the cutout portion 36 through a resin in order to enhance the connection strength.

Further, the exposed portions 27 and 37 of the first and second wirings 22 and 32 are preferably covered by relatively-flexible metal films made of Au and the like using an electroless plating method, in order to reduce stress and connection resistance at the time of connection of the first and second semiconductor chips 11 and 12.

Hereinafter, a method of manufacturing the semiconductor chip 4 of the first embodiment is explained.

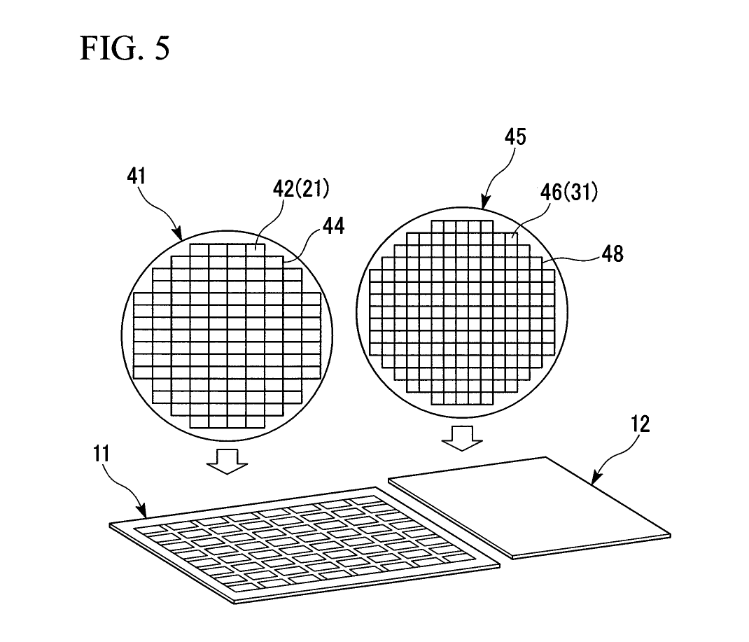

As shown in FIG. 5, various elements and the first wiring layer 22 are formed in an element formation region 42 of a semiconductor wafer 41, which will be the first semiconductor substrate 21 after a dicing process, using a manufacturing process optimized for a DRAM memory cell. Although not shown, not only a DRAM memory cell array, but also a sense amp, a word driver, and the like are arranged in the element formation region 42. The first wiring layer 22 is formed so as to extend to one end of the element formation region 42. Then, the first insulating film 23 is formed over the element formation region 42 so as to cover the elements and the first wiring layer 22.

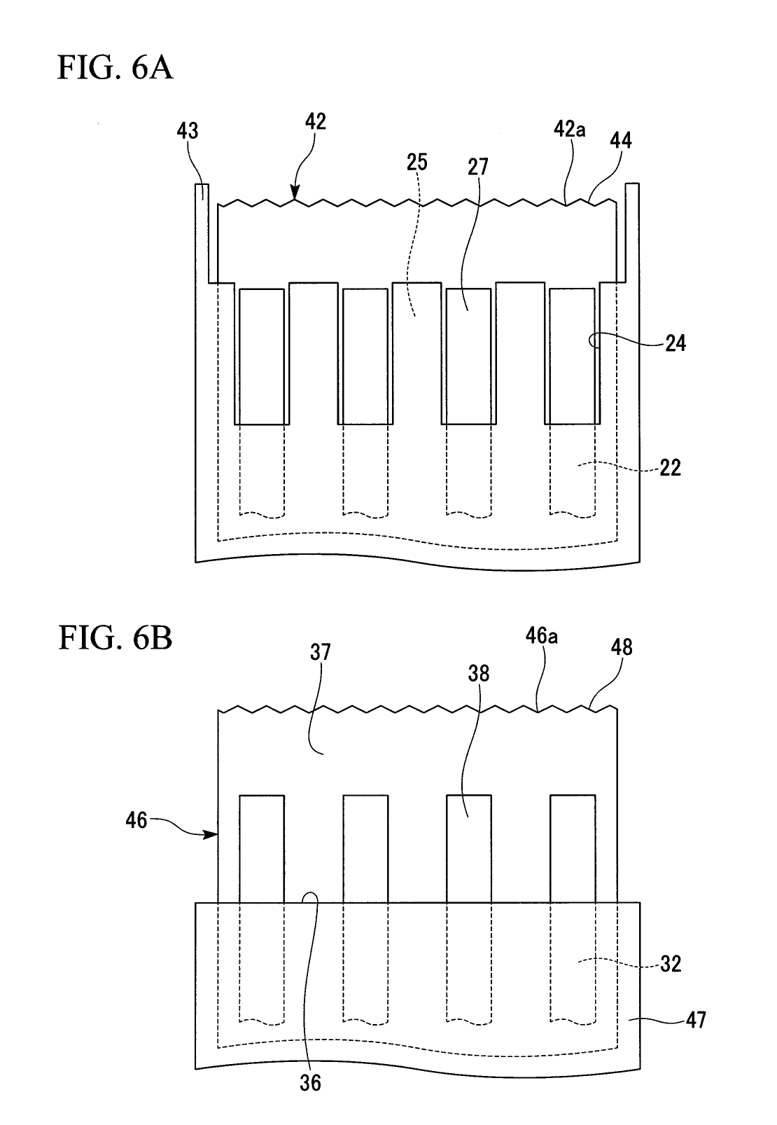

Then, a pattern 43 is formed over the first insulating film 23, as shown in FIG. 6A. Then, the first insulating film 23 is patterned using the pattern 43 as a mask so that the first receiving portions 24 and the first extending portions 25 are formed and the terminal portions 27 of the first wiring layer 22 are exposed.

To expose the terminal portions 27 of the first wiring layer 22, the pattern 43 is formed so as to mask the first wiring layer 22 excluding regions of the terminal portions 27 of the first wiring layer 22 in plan view as shown in FIG. 6A. The pattern 43 is formed so as to extend over one end 42a of the element formation region 42. Accordingly, the first extending portion 25 and the first receiving portion 24 are alternately and precisely arranged along the side 26 of the first semiconductor chip 11 if viewed from the one end 11a of the first semiconductor chip 11 after a dicing process.

Then, the semiconductor wafer 41 is diced along a dicing line 44 into multiple pieces of the first semiconductor chips 11, as shown in FIG. 5. Thus, the first semiconductor chip 11 can be obtained.

Separately from the process of forming the first semiconductor chip 11, various elements and the second wiring layer 32 are formed on an element formation region 46 of a semiconductor wafer 45 as shown in FIG. 5, which will be the second semiconductor substrate 31 after a dicing process. In this case, a manufacturing process for maximizing device performance of a MOS transistor or a manufacturing process for maximally reducing manufacturing costs is used.

Although not shown, a sense amp switching circuit, a main amp, a control circuit for connection to an external device, connection pads, and the like are arranged in the element formation region 46. The second wiring layer 32 is formed so as to extend to one end 46a of the element formation region 46. Then, a second insulating film 33 is formed over the element formation region 46 so as to cover the various elements and the second wiring layer 32.

Then, a pattern 47 is formed over the second insulating film 33, as shown in FIG. 6B. The second insulating film 33 is patterned using the pattern 47 as a mask so that the cutout portion 36 is formed and the terminal portions 38 of the second wiring layer 32 are exposed.

In order to form the exposed portion 37 of the second wiring layer 32, the pattern 47 is formed so that portions of the second insulating film 33, which cover the terminal portions 38 of the second wiring layer 32, are removed. Further, the pattern 47 is formed so as to extend over the one end 46a of the element formation region 46. Accordingly, the second receiving portion 34 and the second extending portion 35 of the second semiconductor chip 12 are alternately and precisely arranged along the side 39 of the second semiconductor chip 12 if horizontally viewed from the side surface 12a thereof after the dicing process.

Then, the second receiving portions 34 are formed by selective etching using the terminal portions 38 of the second wiring layer 32 as masks. At the same time, the second extending portions 35 are formed.

Then, the semiconductor wafer 45 is diced along the dicing line 48 into multiple pieces of the second semiconductor chips 12, as shown in FIG. 5. Thus, the second semiconductor chip 12 including the second receiving portions 34 and the second extending portions 35 that are arranged along the side 39 can be obtained.

Then, the first semiconductor chip 11 is electrically connected to the second semiconductor chip 12. Specifically, the first extending portions 25 of the first semiconductor chip 11 are engaged with the respective receiving portions 34 of the second semiconductor chip 12. At the same time, the second extending portions 35 of the second semiconductor chip 12 are engaged with the first receiving portions 24 of the first semiconductor chip 11. Accordingly, the terminal portions 38 of the second wiring layer 32 in the second extending portions 35 are electrically in contact with the terminal portions 27 of the first wiring layer 22 in the first receiving portions 24.

Thus, the first semiconductor chip 11 is electrically connected to the second semiconductor chip 12, and thereby the semiconductor chip 4 is formed. Although not shown, a third semiconductor chip, on which a low switching circuit, a control circuit, and the like are formed, may be formed on another wafer according to need so as to be electrically connected to another side surface of the first semiconductor chip 11 in a similar manner.

According to the first embodiment of the present invention, the terminal portions 27 of the first wiring layer 22 are directly and electrically connected to the terminal portions 37 of the second wiring layer 32. Therefore, the number of connection wirings between the first and second semiconductor chips 11 and 12 can be increased. For example, more than 1000 wirings can be connected.

Additionally, the first extending portions 27 of the semiconductor chip 11 are directly engaged with the respective second receiving portions 34 of the second semiconductor chip 12. Therefore, the first wiring layer 22 can be precisely connected to the second wiring layer 32, thereby preventing connection defects.

Further, substantially the same number of wirings in a semiconductor chip of the related art can be connected. For this reason, a memory cell portion having a dedicated structure formed by a complicated process, and a logic portion for controlling the memory cell portion can be formed on different wafers, and then the two portions can be connected after a dicing process. Accordingly, a thermal treatment required for forming the memory cell portion does not affect the logic portion, thereby enhancing device performance of the logic portion.

Moreover, even when a taller capacitor, such as an STC, is formed in order to maintain characteristics of the capacitor with miniaturization of DRAM memory cells, the logic portion and the memory cell portion are separately formed, thereby enabling optimization of a wiring structure of the logic portion. Accordingly, an increase in yield and reliability, a reduction in wiring resistance, and the like can be achieved.

Additionally, the transistor formation processes for the memory cell portion and the logic portion can be separately carried out. For this reason, a lithography process for separating the memory cell portion from the logic portion is not required, thereby enabling a reduction in costs.

Further, formation of LDD regions, impurity implantation, and the like can be carried out separately for the memory cell portion and the logic portion, thereby enhancing device performance of each portion. Further, a three-dimensional transistor for a memory cell and a strained transistor for a peripheral circuit can be easily introduced with further miniaturization of semiconductor devices.

As used herein, the following directional terms “forward,” “rearward,” “above,” “downward,” “vertical,” “horizontal,” “below,” and “transverse,” as well as any other similar directional terms refer to those directions of an apparatus equipped with the present invention. Accordingly, these terms, as utilized to describe the present invention should be interpreted relative to an apparatus equipped with the present invention.

The terms of degree such as “substantially,” “about,” and “approximately” as used herein mean a reasonable amount of deviation of the modified term such that the end result is not significantly changed. For example, these terms can be construed as including a deviation of at least ±5 percent of the modified term if this deviation would not negate the meaning of the word it modifies.

It is apparent that the present invention is not limited to the above embodiments, but may be modified and changed without departing from the scope and spirit of the invention.

For example, although it has been explained in the first embodiment that the first semiconductor chip 11 includes a circuit that directly controls the DRAM memory cell and the memory cell array, the first semiconductor chip 11 may include a sense amp, a word-line driver, a data bus buffer, a control circuit, and the like.

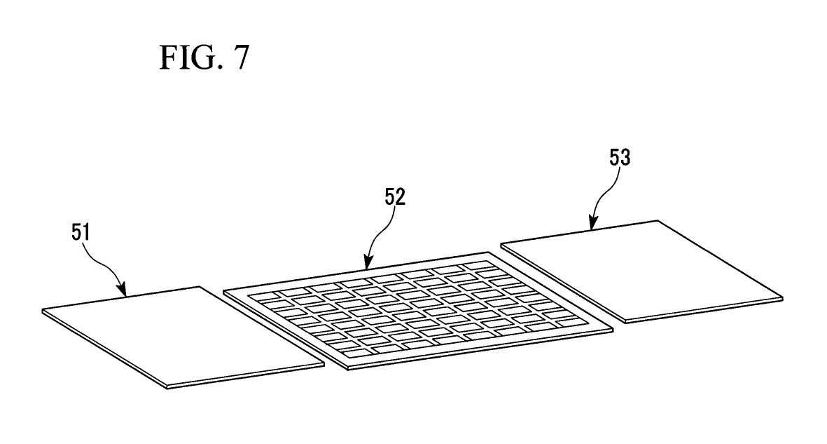

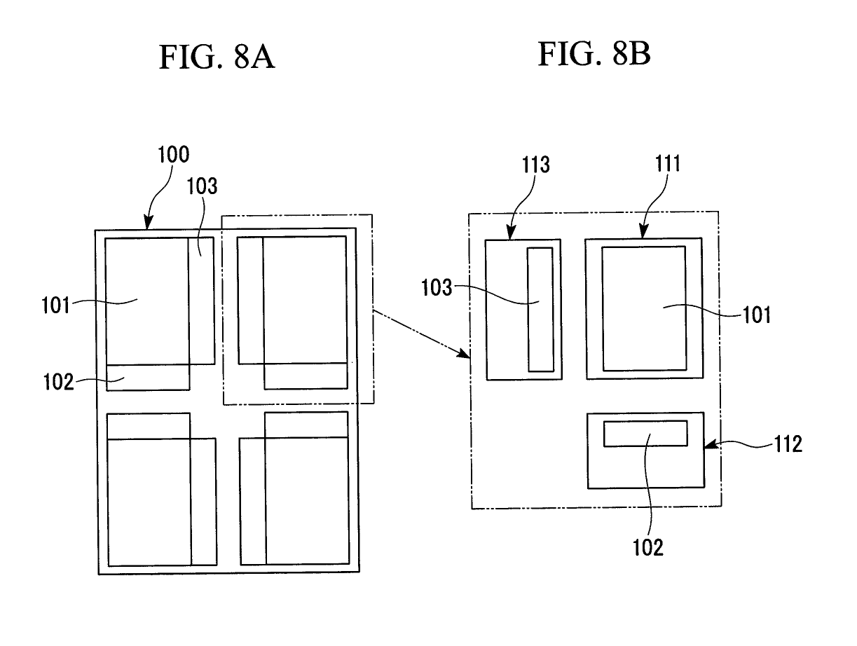

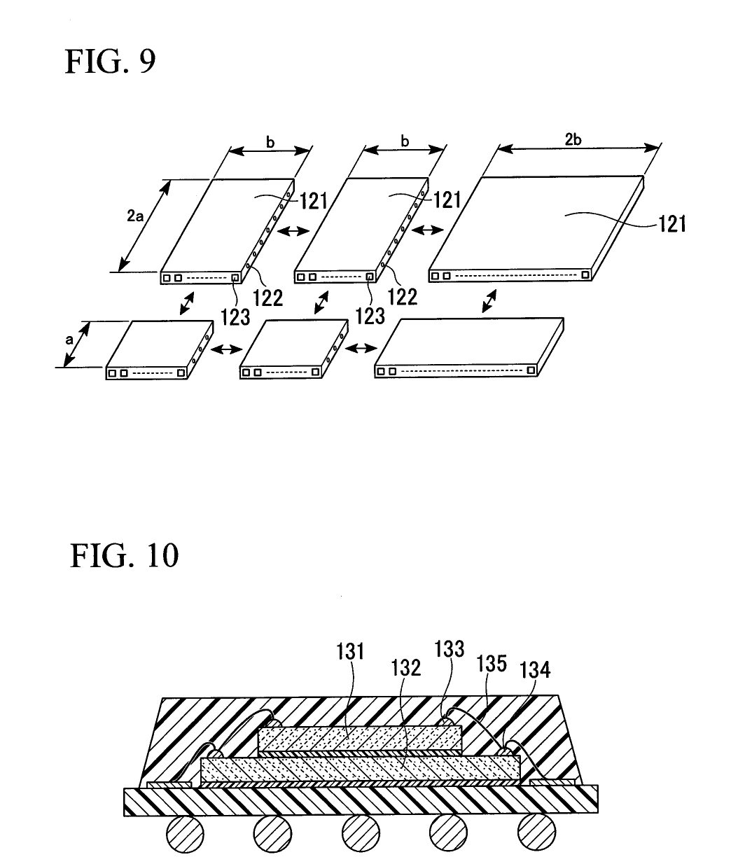

Further, although it has been explained in the first embodiment that two semiconductor chips are engaged with each other, three or more semiconductor chips, such as semiconductor chips 51, 52, and 53 shown in FIG. 7, may be engaged with one another.

The present invention is widely applicable to semiconductor device manufacturing industries.

What is claimed is:

1. A semiconductor device comprising:
a first semiconductor chip comprising a first engaging portion, the first engaging portion comprising a first conductor; and
a second semiconductor chip comprising a second engaging portion engaged with the first engaging portion, the second engaging portion comprising a second conductor being electrically in contact with the first conductor.

2. The semiconductor device according to claim 1, wherein
the first conductor comprises a first wiring layer, and
the second conductor comprises a second wiring layer that is in contact with the first wiring layer.

3. The semiconductor device according to claim 2, wherein
the first wiring layer comprises a first metal film; and
the second wiring layer comprises a second metal film that is in contact with the first metal film.

4. The semiconductor device according to claim 3, wherein
the first metal film is a first flexible metal film, and
the second metal film is a second flexible metal film.

5. The semiconductor device according to claim 1, wherein
the first engaging portion has a first side surface,
the second engaging portion has a second side surface facing the first side surface, and
the semiconductor device further comprises:
a resin fixing the first and second side surfaces.

6. The semiconductor device according to claim 1, wherein
the first engaging portion is a protruding portion, and
the second engaging portion is a receiving portion.

7. The semiconductor device according to claim 6, wherein the protruding portion is substantially the same size as the receiving portion.

8. A semiconductor device comprising:
a wiring layer; and
an insulating layer over the wiring layer, the insulating layer comprising a receiving portion adjacent to a first side surface of the insulating layer, the receiving portion having a second side surface and a first bottom surface, the second side surface vertically extending from the wiring layer, the second side surface connecting to the first side surface, the first bottom surface being a first upper surface of a first portion of the wiring layer.

9. The semiconductor device according to claim 8, wherein the second side surface and the first bottom surface define a space.

10. The semiconductor device according to claim 9, wherein the space is a trench groove.

11. The semiconductor device according to claim 8, wherein the insulating layer further comprises first and second extending portions that outwardly extend, the receiving portion being disposed between the first and second extending portions.

12. The semiconductor device according to claim 8, further comprising:
a metal film covering the first upper surface.

13. The semiconductor device according to claim 12, wherein the metal film is a flexible metal film.

14. A semiconductor device comprising:
a substrate; and
a wiring layer over the substrate, a stack of the substrate and the wiring layer comprising first and second receiving portions that are adjacent to a first side surface of the stack, first and second bottom surfaces of the first and second receiving portions being included in the substrate, respectively, second and third side surfaces of the first and second receiving portions vertically extending from the first and second bottom surfaces, respectively.

15. The semiconductor device according to claim 14, wherein
the first bottom surface and the second side surface define a first space, and
the second bottom surface and the third side surface define a second space.

16. The semiconductor device according to claim 15, wherein
the first and second spaces are first and second trench grooves, respectively.

17. The semiconductor device according to claim 14, wherein the stack further comprises an extending portion defined by the first and second receiving portions.

18. The semiconductor device according to claim 17, wherein the extending portion comprises a first portion of the wiring layer.

19. The semiconductor device according to claim 18, further comprising:
a metal film covering the first portion.

20. The semiconductor device according to claim 19, wherein the metal film is a flexible metal film.
